(19) United States
(12) Patent Application Publication
(10) Pub. No.: US 2019/0096751 A1
(43) Pub. Date: Mar. 28, 2019

(54) Dual Damascene Process for Forming Vias and Interconnects in an Integrated Circuit Structure

(71) Applicant: Microchip Technology Incorporated, Chandler, AZ (US)

(72) Inventors: Justin Hiroki Sato, West Linn, OR (US); Bonnie Hamlin, Gresham, OR (US); Andrew Taylor, Tigard, OR (US); Bomy Chen, Newark, CA (US); Brian Hennes, Portland, OR (US)

(73) Assignee: Microchip Technology Incorporated, Chandler, AZ (US)

(21) Appl. No.: 16/103,538

(22) Filed: Aug. 14, 2018

Related U.S. Application Data
(60) Provisional application No. 62/563,302, filed on Sep. 26, 2017.

(51) Int. Cl. H01L 21/768

(52) U.S. Cl. CPC H01L 21/76808; H01L 21/76816; H01L 21/76843

(57) ABSTRACT

A method of forming interconnects in a semiconductor device is provided. A mask including first and second openings is formed over a non-conductive structure. An etch is performed through the mask openings to define (a) a via trench having a via trench width and (b) an interconnect trench having a smaller width than the via trench width. A fill layer is deposited over the structure and (a) fills only a partial width of the via trench to thereby define via trench cavity and (b) fills the full width of the interconnect trench. A further etch is performed through the via trench cavity to form a via opening extending downwardly from the via trench. The remaining fill layer material is removed. The interconnect trench, via trench, and via opening are metallized to form a trench interconnect, a via interconnect, and a via extending downwardly from the via interconnect.

### RELATED PATENT APPLICATION

This application claims priority to commonly owned U.S. Provisional Patent Application No. 62/563,302 filed Sep. 26, 2017, the entire contents of which are hereby incorporated by reference for all purposes.

### TECHNICAL FIELD

The present disclosure relates to semiconductor interconnects and, more particularly, to a dual damascene process for forming metal vias and interconnects in an integrated circuit structure, e.g., using a single photomask.

### BACKGROUND

Forming metal interconnects, e.g., vias and trench interconnects, in a semiconductor structure typically requires numerous process steps including the use of multiple photomasks, for example in to create dual-damascene copper interconnects. However, photolithography costs are often the most expensive item in a wafer manufacturing process.

### BRIEF DESCRIPTION OF THE DRAWINGS

Example aspects of the present disclosure are described below in conjunction with the figures, in which:

FIGS. 1A-1G are cross-sectional views illustrating an example method for forming metal vias and lines using a single mask dual damascene process, according to one example embodiment;

FIG. 2 illustrates example dimensional parameters relating to various structures shown in FIGS. 1A and 1B, e.g., dimensions of interconnect trenches and the conformal fill/spacer layer deposited in the trenches, according to example embodiments;

FIG. 3 illustrates a top of a trench interconnect having a via extending downwardly from a via interconnect arranged along the length of the trench interconnect, and showing example dimensional parameters, according to one embodiment of the present invention;

FIGS. 4A-4D illustrate example dimensional parameters of metal vias and interconnects formed according to an example embodiment of the invention, as compared with a conventional design;

FIGS. 5A-5H are cross-sectional views illustrating an example method for forming metal vias and lines using a single mask dual damascene process, according to one example embodiment; and

FIG. 6 illustrates an example metal-oxide-metal (MOM) capacitor formed according to one embodiment of the invention.

### SUMMARY

Embodiments of the present disclosure provide a single-mask dual-damascene process for forming metal interconnects (e.g., vias and trench interconnects) in an integrated circuit structure. Such interconnects may be used in any suitable semiconductor or electronic device, such as a microcontroller or processor, for example. Embodiments of the present disclosure may by implemented in a less expensive manner than conventional interconnects. For example, in some embodiments, interconnects formed according to embodiments of the present disclosure may be the result of back-end-of-line processing that reduce the minimum number of steps required to produce a working and user friendly product. In some embodiments, such interconnects may be created with a reduced number of lithography steps to create dual-damascene copper interconnects. In addition, such interconnects may be created with a process that reduces the conventional limitations associated with the use of via pitch.

In one embodiment, interconnects may be formed using a self-aligned dual damascene process that uses a single photolithography mask or step. In such an embodiment, a single mask or step may be used as opposed to other processes that may use two such masks or steps. In another embodiment, the process may include elimination of a via mask. In such an embodiment, interconnects may instead be defined during a trench mask. The vias may be self-aligned, and may be smaller than can be resolved with currently available scanners.

One embodiment provides a method of forming conductive structures in a semiconductor device. A hard mask may be formed over a non-conductive structure, the hard mask including a first hard mask opening and a second hard mask opening, the first hard mask opening having a greater width than the second hard mask opening. An etch may be performed through the first and second hard mask openings into the non-conductive structure to define (a) a via trench having a via trench opening width defined by the first hard mask opening, and (b) an interconnect trench having an interconnect trench width defined by the second hard mask opening and smaller than the via trench width. A spacer layer may be deposited and extends into both the via trench and the interconnect trench such that (a) the spacer layer extending into the via trench fills only a portion of the via trench width to thereby define an open via trench cavity, and (b) the spacer layer extending into the interconnect trench fills the full interconnect trench width. A further etch may be performed through the via trench cavity to form a via opening extending downwardly from the via trench. The spacer layer maybe removed from the via trench and the interconnect trench. Finally, the interconnect trench, the via trench, and the via opening may be filled with a conductive material (e.g., copper) to form (a) a trench interconnect in the interconnect trench, (b) a via interconnect in the via trench, and (c) a via in the via opening, wherein the via extends downwardly from the via interconnect.

### DETAILED DESCRIPTION

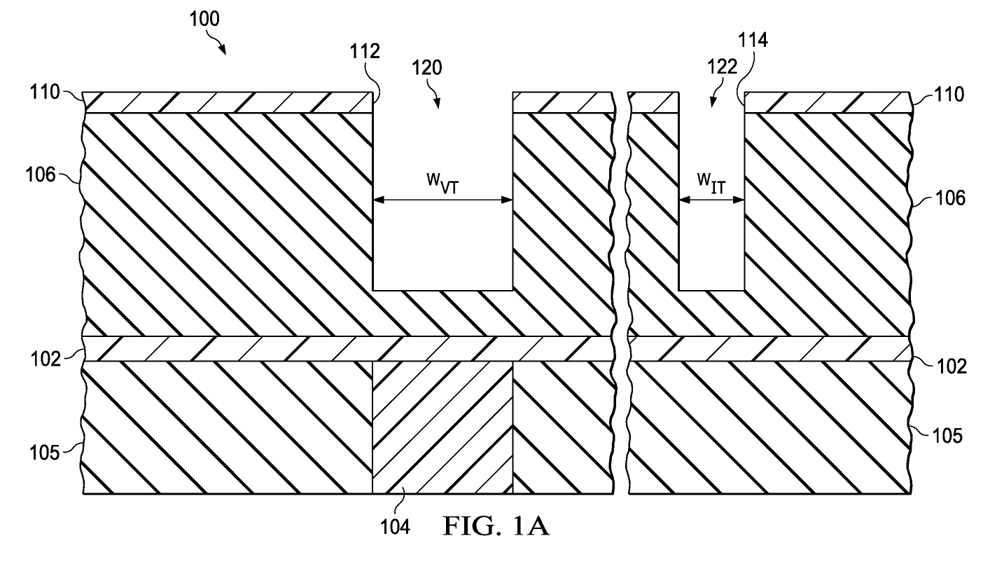

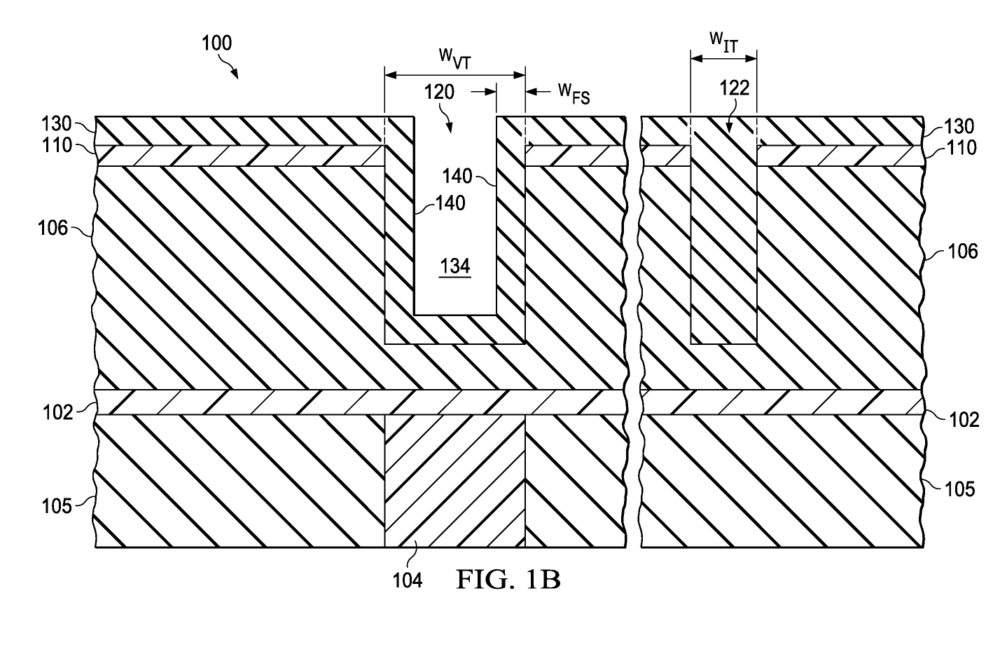

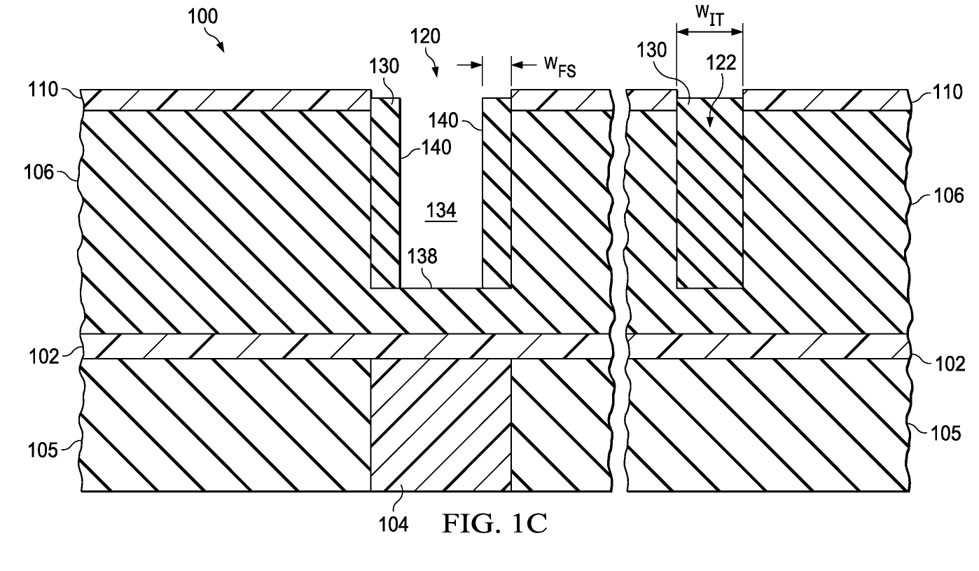

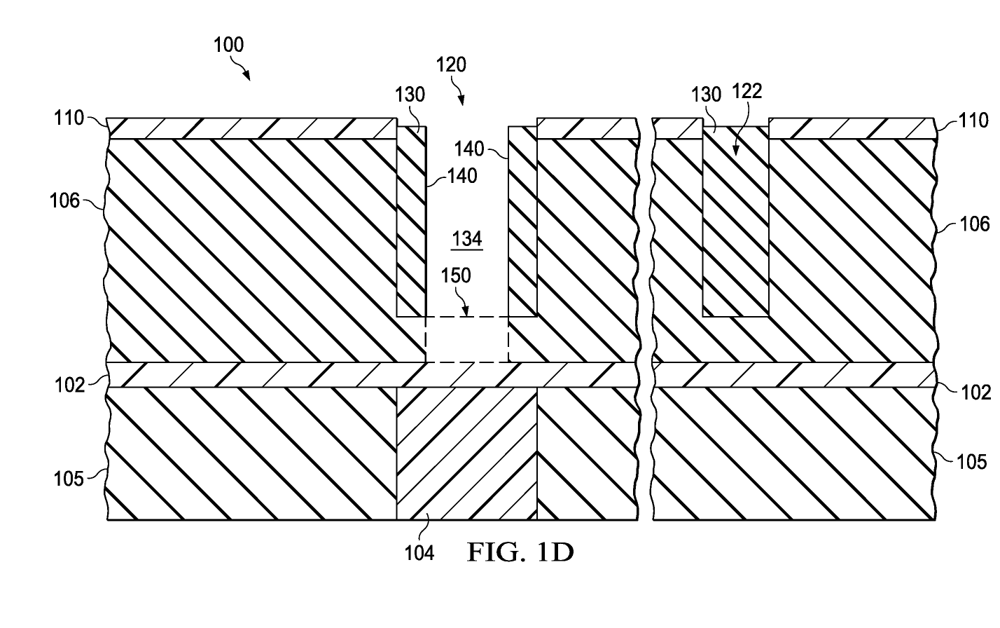

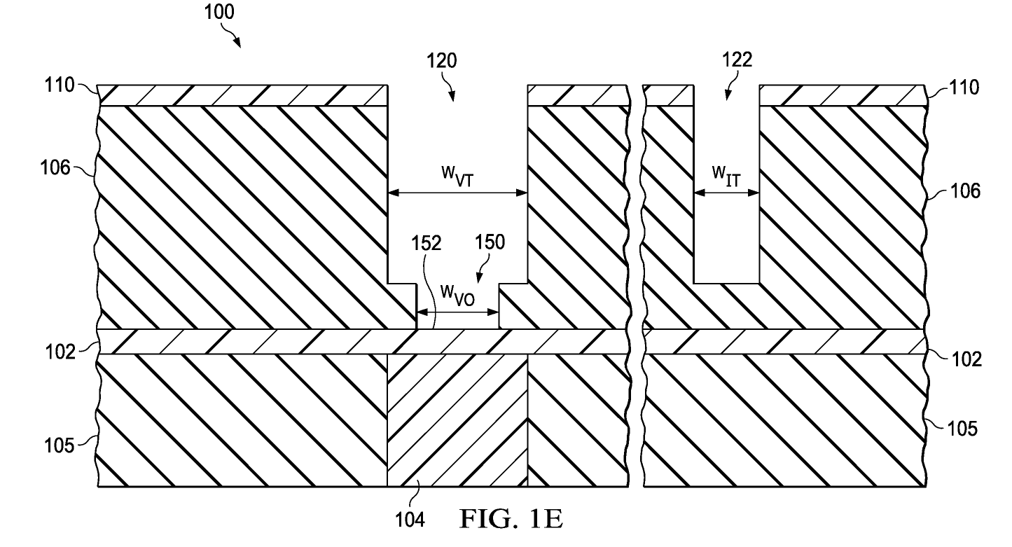

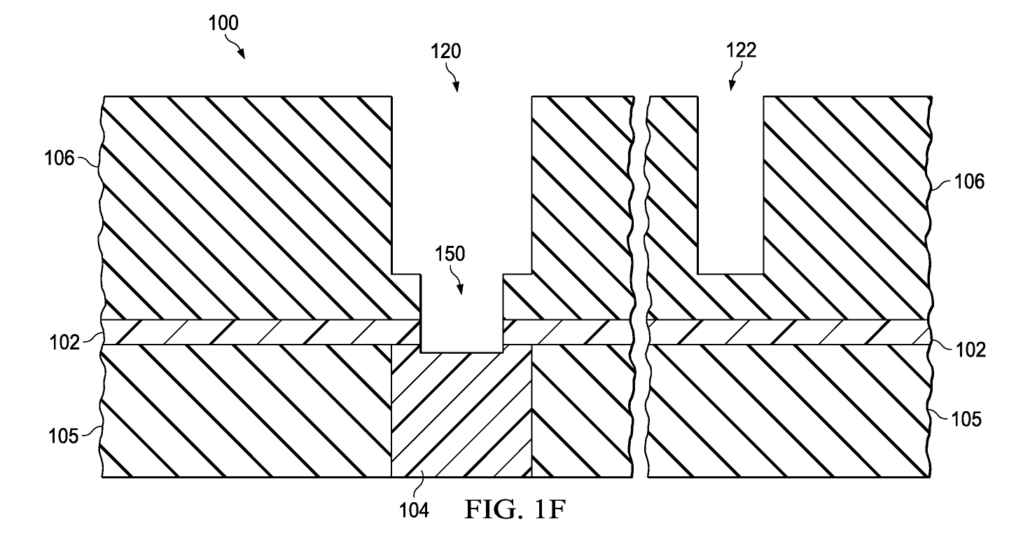

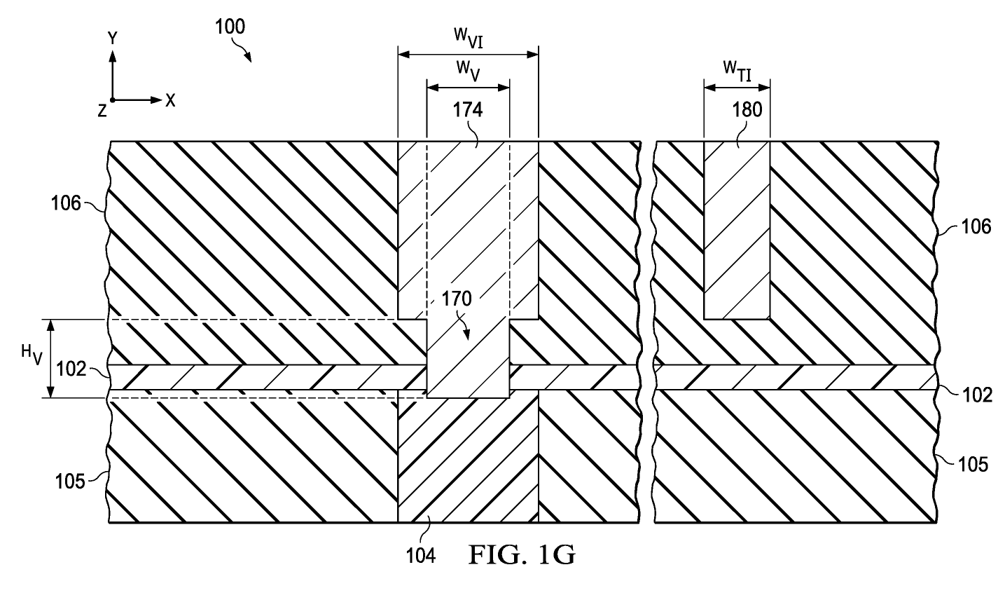

FIGS. 1A-1G are cross-sectional views illustrating an example method for forming conductive vias and interconnects in a semiconductor device using a single mask dual damascene process, according to one example embodiment.

As shown in FIG. 1A, a semiconductor device structure 100 may include a lower metal 102 (e.g., metal interconnect or device) formed in a substrate or dielectric region 105 below a bottom barrier 104. The lower barrier layer 104 may be of a same material as a later-formed hard mask 110, discussed below. A non-conductive layer 106, e.g., an inter-metal dielectric (IMD) layer, may be formed above the lower barrier layer 102. A hard mask 110 may be arranged or formed above the IMD layer 106. Hard mask 110 may include a number of openings, including a first hard mask opening 112 having a first width for forming a conductive via and a second hard mask opening 114 having a first width smaller than the first width, for forming a conductive interconnect, as discussed below.

An etch may be performed through the first and second hard mask openings 112 and 114 to form a via trench 120 and an interconnect trench 122 in the IMD layer 106. As shown, the via trench 120 may have a width W_{VT}, and interconnect trench 122 may have a width W_{IT} less than the via trench width W_{VT}, wherein widths W_{VT} and W_{IT} are defined by the respective widths of the first and second hard mask openings 112 and 114. As discussed below, via trench width W_{VT} and interconnect trench width W_{IT} may be selected (by selected dimensioning of the hard mask openings 112 and 114) based on a thickness or width of a fill layer subsequently formed over the structure and extending into the via trench 120 and interconnect trench 122. Further, in some embodiments, the via trench width W_{VT} may be approximately the same as, or greater than, the corresponding width of lower metal 104.

Via trench 120 and interconnect trench 122 may thus be formed using only a single hard mask, and thus only a single photolithography process.

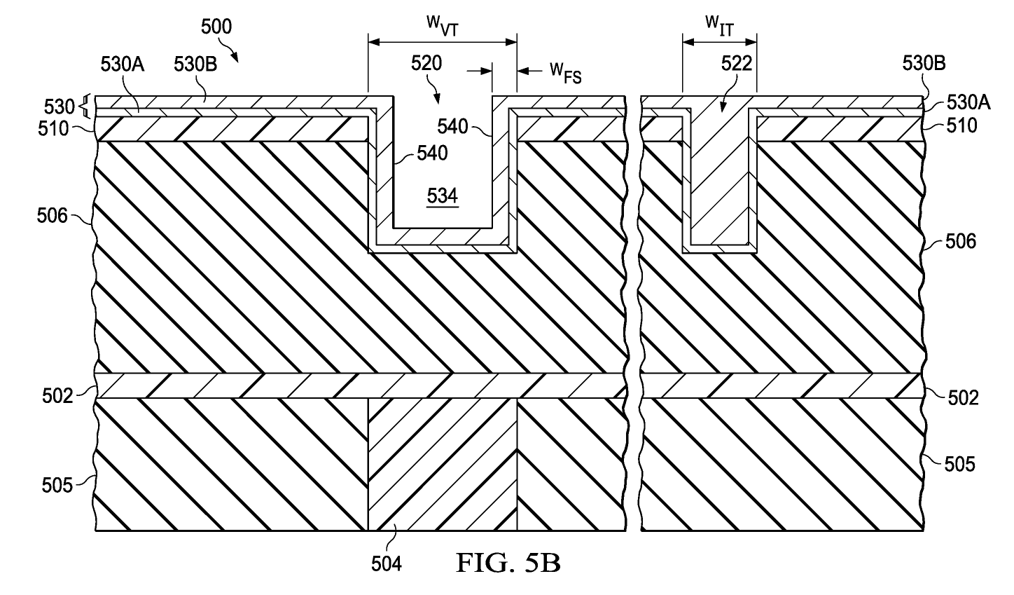

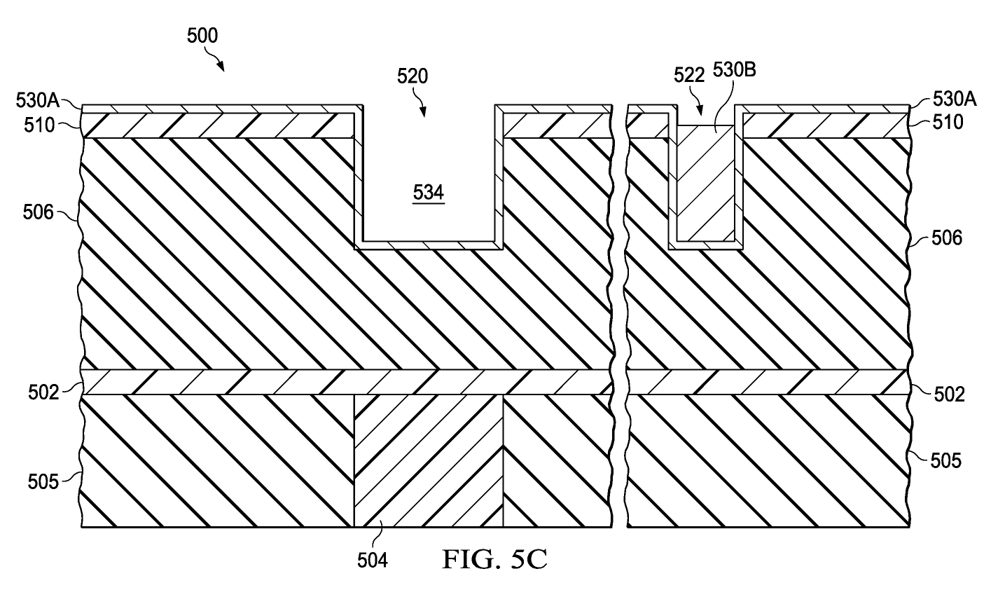

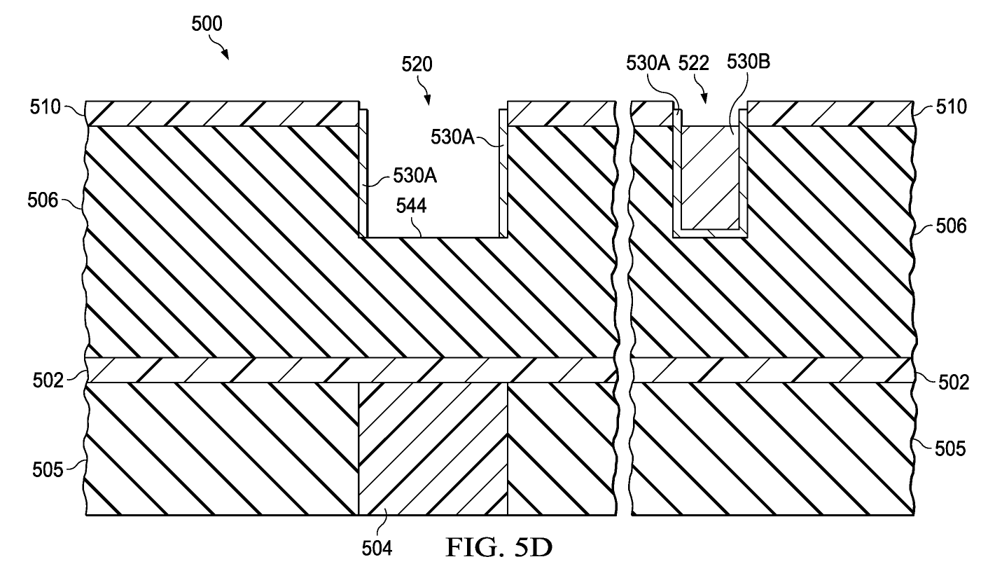

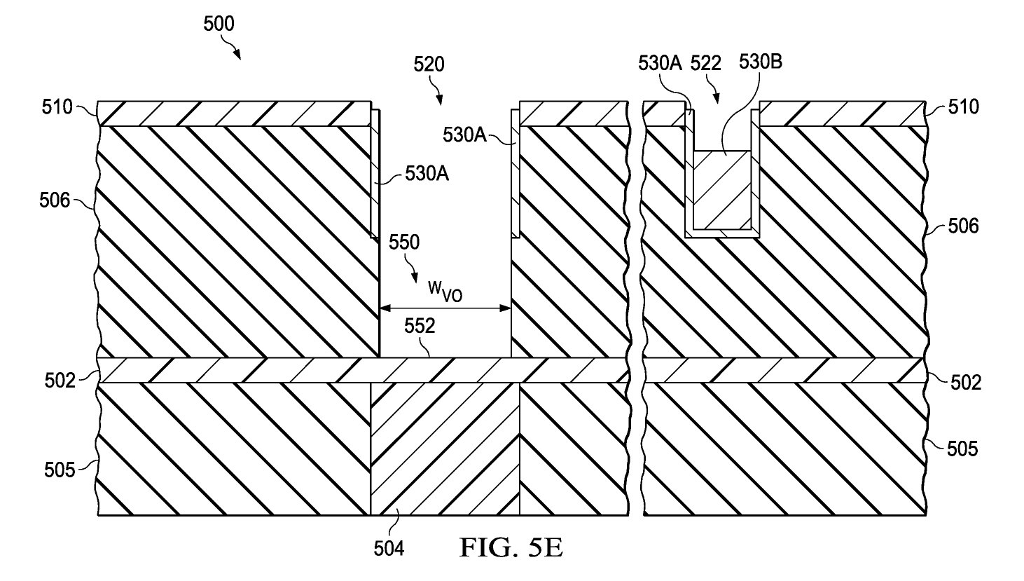

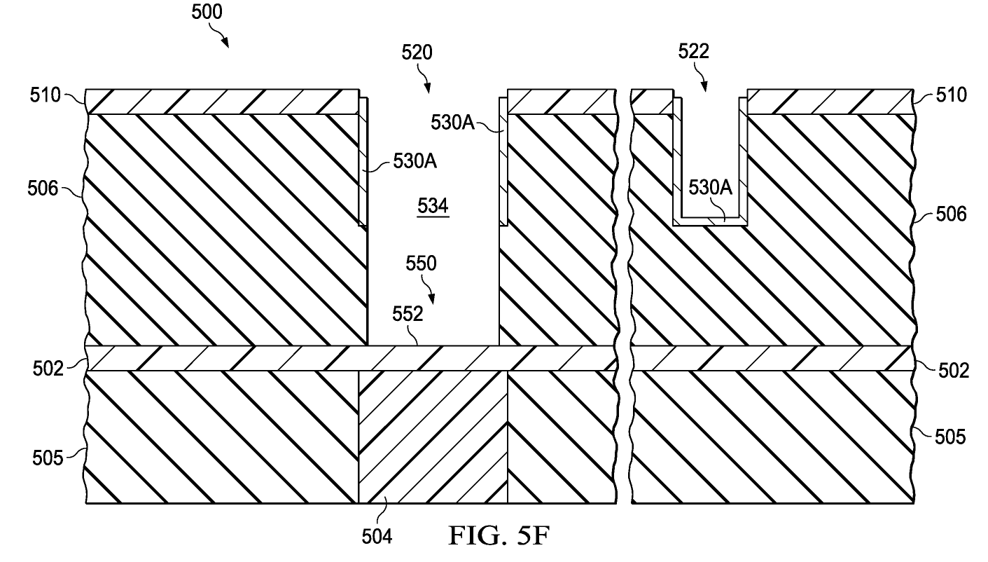

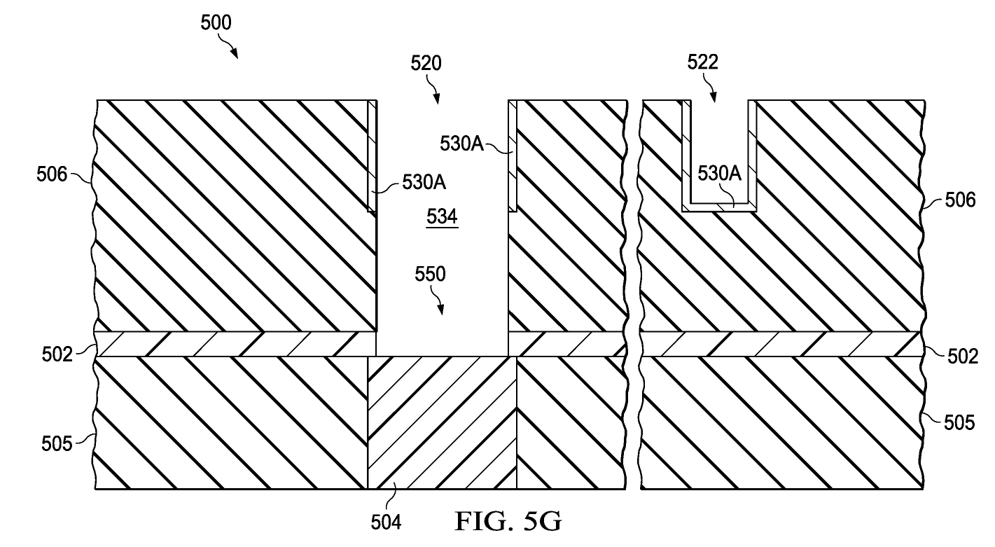

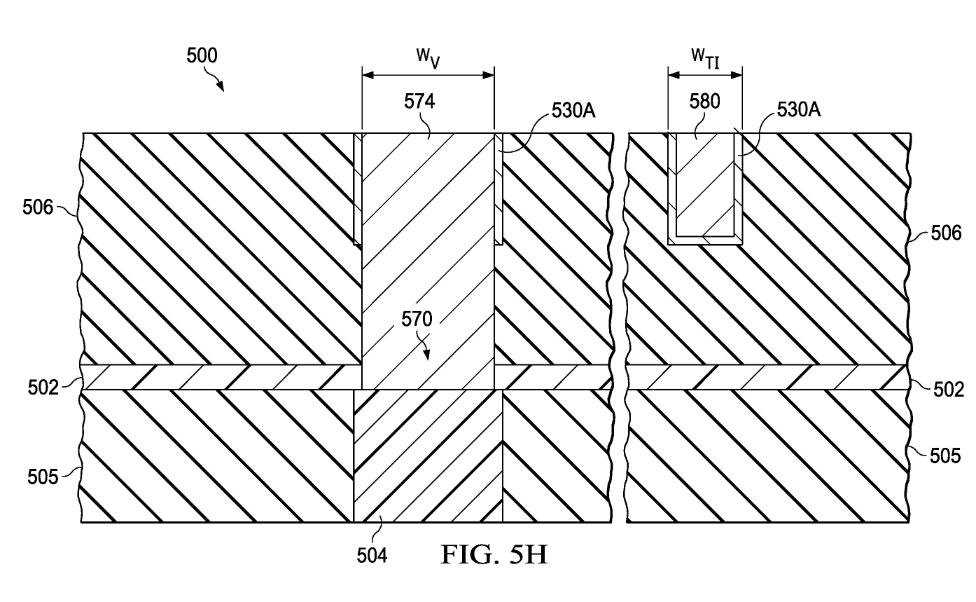

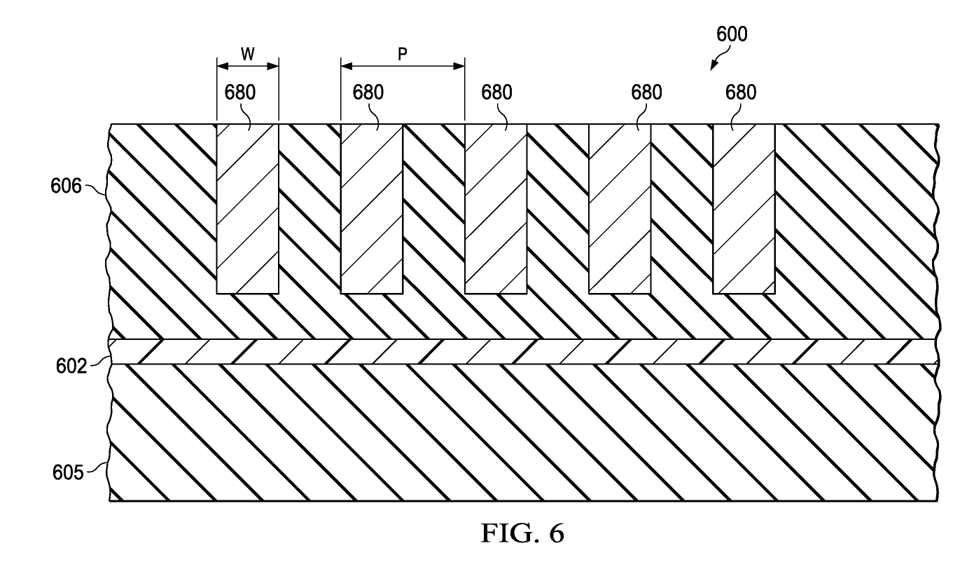

As shown in FIG. 1B, a sacrificial conformal fill layer (also referred to as a spacer layer) 130 may be deposited over the hard mask 110 and extending down into via trench 120 and interconnect trench 122. Sacrificial conformal fill layer 130 may include a single material layer or a stack of multiple layers (“sublayers”) of one or multiple different materials (FIGS. 5A-5H discussed below describe an example embodiment including a fill layer 130 consisting of two sublayers). In some embodiments, fill layer 130 may comprise an ultra-conformal material, a dielectric, or a conductor, for example. In some embodiments, fill layer 130 may comprise silicon nitride (SiN), silicon carbide (SiC), titanium nitride (TiN), tantalum nitride (TaN), tungsten (W), cold polysilicon Poly Si, SiN, aluminum, oxide. In some embodiments, fill layer 130 may comprise any material(s) with a high etch selectivity to the hardmask 130 and suitable conformal deposition properties. Alternatively, fill layer 130 may comprise the same material as hardmask 130, wherein such material has a very high etch selectivity to the IMD substrate 106.

As shown in FIG. 1B, conformal fill layer 130 may be formed with a selected thickness that defines vertical sidewall regions 140 within via trench 120 with a selected sidewall width W_{FS}. The width W_{VT} of via trench 120 may be greater than double the fill layer sidewall width W_{FS}, such that a via trench cavity 134 is defined between opposing sidewall regions 140 of fill layer 130. In contrast, the width W_{IT} of interconnect trench 122 may be less than or equal to double the fill layer width in the via trench, W_{FS}, such that the full width W_{IT} of interconnect trench 122 is filled with fill layer material, as shown.

As shown in FIG. 1C, a fill layer etch may be performed to remove portions of the sacrificial fill layer 130, including portions of layer 130 outside via trench 120 and interconnect trench 122 (i.e., all or portions of fill layer 130 overlying hard mask 110) and a portion of layer 130 lining the bottom of via trench 120 to thereby expose an upper surface 138 of IMD 106.

After the etch, vertical sidewall regions 140 of conformal fill layer 130, having a lateral width W_{FS}, may remain on the lateral sidewalls of via trench 120, with via trench cavity 134 defined between opposing fill layer sidewall regions 140. In addition, the full width W_{IT} of interconnect trench 122 may remain filled with fill layer material, as shown. In some embodiments, hard mask 110 may be used as an endpoint for the etch.

As shown in FIG. 1D, a further etch may be performed through the via trench cavity 134 to define a via opening 150 extending from the bottom of via trench 120 and having a via opening width W_{VO}. The etch may be selective to hard mask 110 and fill material 130, thus etching only through the IMD layer 106 at the exposed region between the fill layer sidewall regions 140. Thus, via opening 150 may be self-aligned by the fill layer sidewall regions 140. The etch may stop on the lower barrier layer (e.g., hard mask material) 102 to expose an upper surface 152 of lower barrier layer 102.

As shown in FIG. 1E, the fill layer sidewall regions 140 within via trench 120 may be removed by a suitable etch or other removal process, to define an opening extending through IMD 160 and including via trench 120 having a width W_{VT} and via opening 150 having a narrower width Z (as a function of the fill layer sidewall width W_{FS} shown in FIG. 1C).

As shown in FIG. 1F, a barrier etch may be performed through the region of the lower barrier layer 102 exposed through via opening 150 (i.e., at exposed surface 152) and stopping at or below a top surface of the underlying lower metal region 104, to thereby extend the via opening 150 downwardly into contact with the lower metal region 104. The etch may also remove hard mask 110, or hard mask 510 may be removed in a separate step.

As shown in FIG. 1G, a metallization and chemical-mechanical planarization (CMP) may be performed to (a) fill via opening 150 to form a conductive via 170 in contact with lower metal contact 104 and having a via width W_{V}, (b) fill via trench 120 to form a conductive via interconnect 174 overlying and in contact with via 170 and having a width W_{VI}, and (c) fill interconnect trench 122 to form a conductive trench interconnect 180 having a width W_{TI}. Any suitable metal or other electrically conductive material may be used for the metallization, e.g., copper, tungsten, etc.

As shown, the via width W_{V} may be less than the via interconnect width W_{VI}, resulting from the fill layer sidewall thickness. In some embodiments, the via width W_{V} and via height H_{V} may be selectively designed to provide a desired or required conductance through via 170. For example, as the via width W_{V} is decreased, the via height H_{V} may be increased to compensate.

The relationship between the via width W_{V} and the trench interconnect width W_{TI} may depend on design parameters or requirements of the particular embodiment. In particular, the via width W_{V} may be less than, greater than, or equal to the trench interconnect width W_{TI}, depending on the particular embodiment.

In some embodiments, each cross-sectional view shown in FIGS. 1A-1G is defined by a plane cutting through two adjacent metal lines extending parallel to each other in a direction into/out of the page, i.e., along the z-axis indicated in FIG. 1G, wherein the left side of each figure (showing via 170 and via interconnect 174) represents a cross-sectional view of a first metal line having a via extending downwardly therefrom and the right side of each figure (showing trench interconnect 180) represents a cross-sectional view of a second metal running parallel to the first metal line (which may also include a downwardly-extending trench at another location along the z-axis direction).

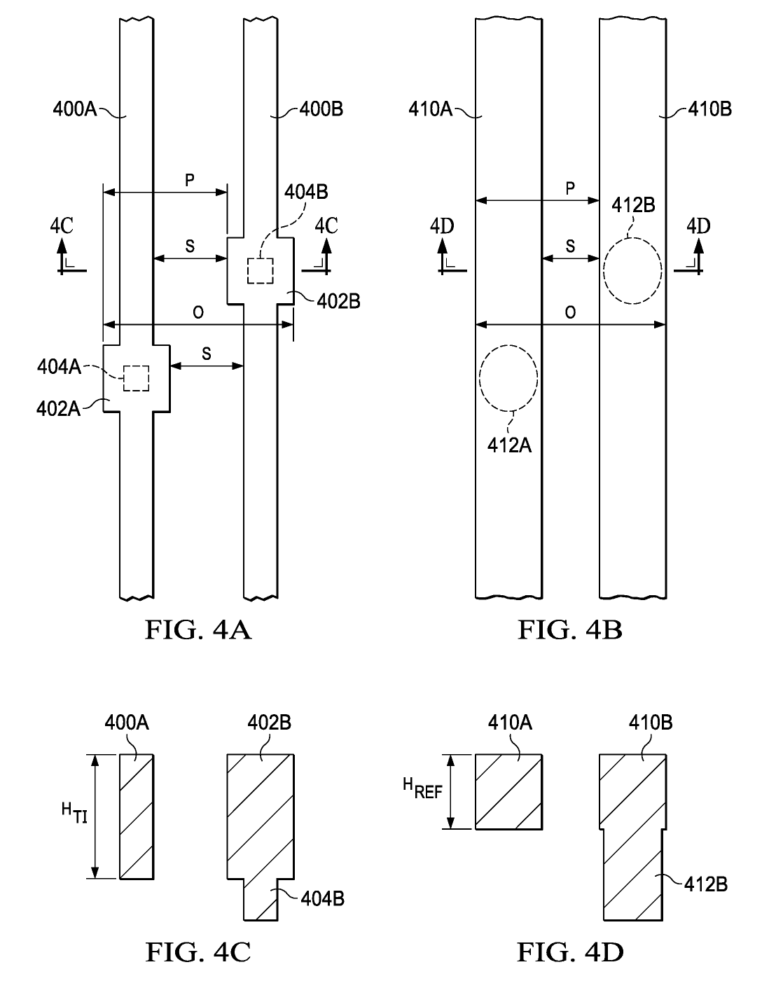

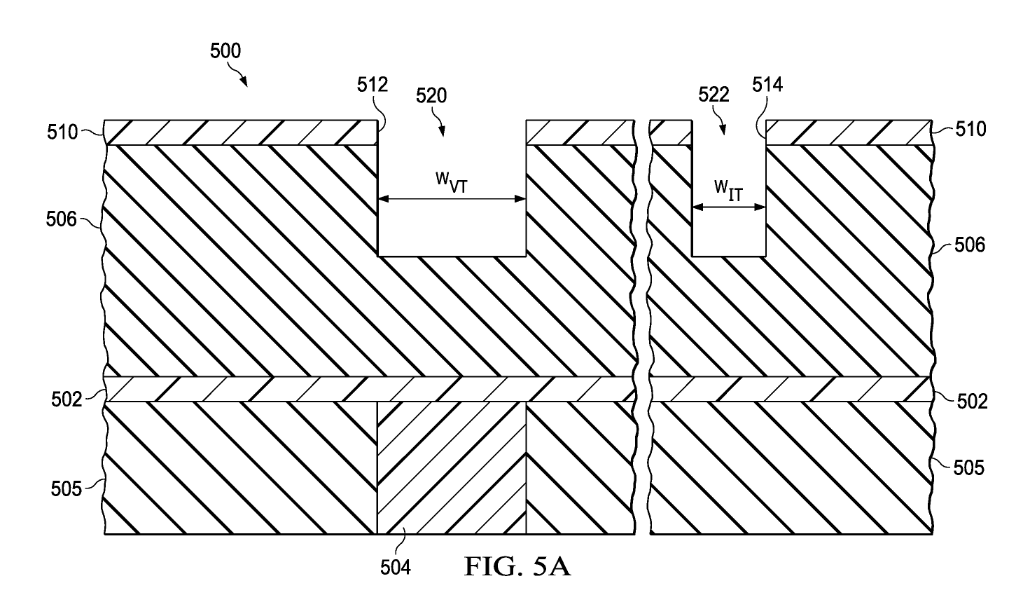

In some embodiments, each cross-sectional view shown in FIGS. 1A-1G is defined by a plane cutting through two adjacent metal lines extending parallel to each other in a direction into/out of the page, i.e., along the z-axis indicated in FIG. 1G, wherein the left side of each figure (showing the construction of via 170 and via interconnect 174) represents a cross-sectional view of a first metal line having a via extending downwardly therefrom and the right side of each figure (showing the construction of trench interconnect 180) represents a cross-sectional view of a second metal running parallel to the first metal line (which may also include a downwardly-extending trench at another location along the z-axis direction). For example, FIG. 1G may represent a cross-sectional view taken through line A-A shown in FIG. 4A, discussed below.

In other embodiments, the left and right sides of each FIG. 1A-1G represents a cross-section taken through a pair of parallel planes passing through a single metal line that extends along the z-axis shown in FIG. 1G and has a via extending downwardly the interconnect. That is, the left side of each figure, showing the construction of via 170 and via interconnect 174, represents a cross-section of the metal line at a location where a via extends downwardly from the metal line, while the right side of each figure, showing the construction of trench interconnect 180 (i.e., the metal line extending along with z-axis), represents a cross-section of the metal line at a location offset in the z-direction from the location of the via.

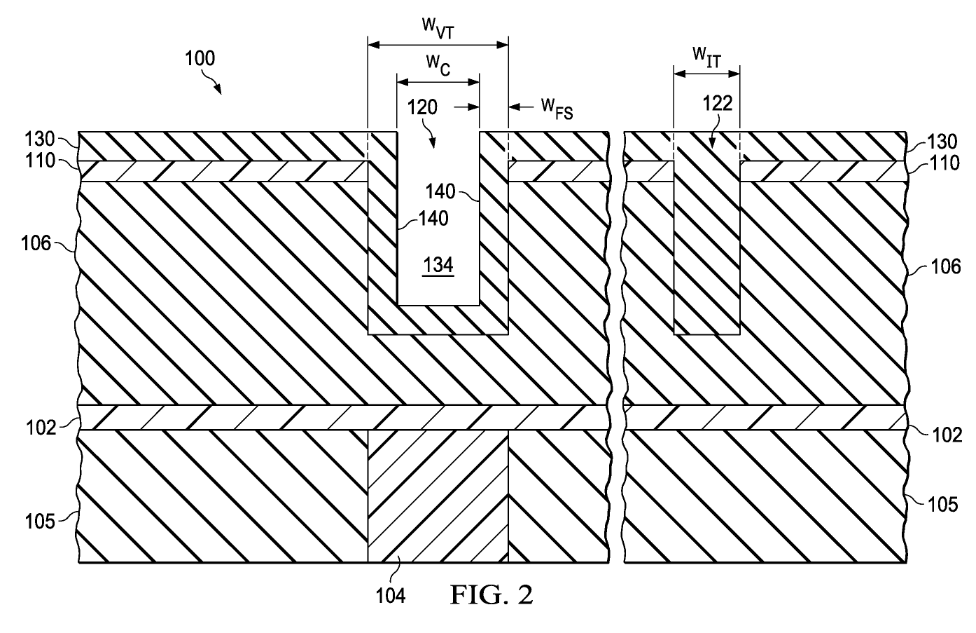

FIG. 2 illustrates example dimensional parameters relating to various structures shown in FIGS. 1A and 1B, e.g., dimensions of trenches 120 and 122 and the conformal fill layer 130 deposited in the trenches 120, 122, according to example embodiments.

The via trench width W_{VT} of via trench 120 may be greater than two times the fill layer sidewall width W_{FS}, to define via trench cavity width W_{C}. In other words, W_{VT}=2*W_{FS}+W_{C}. The trench cavity width W_{C} may be equal or approximately equal (e.g., ±10% or ±15%) the final via critical dimension (of via 170).

In contrast, the interconnect trench width W_{IT} may be less than or equal to two times the fill layer sidewall width W_{FS}, such that the full interconnect trench width W_{IT} is filled with fill material 130. In other words, W_{IT}≤2*W_{FS}.

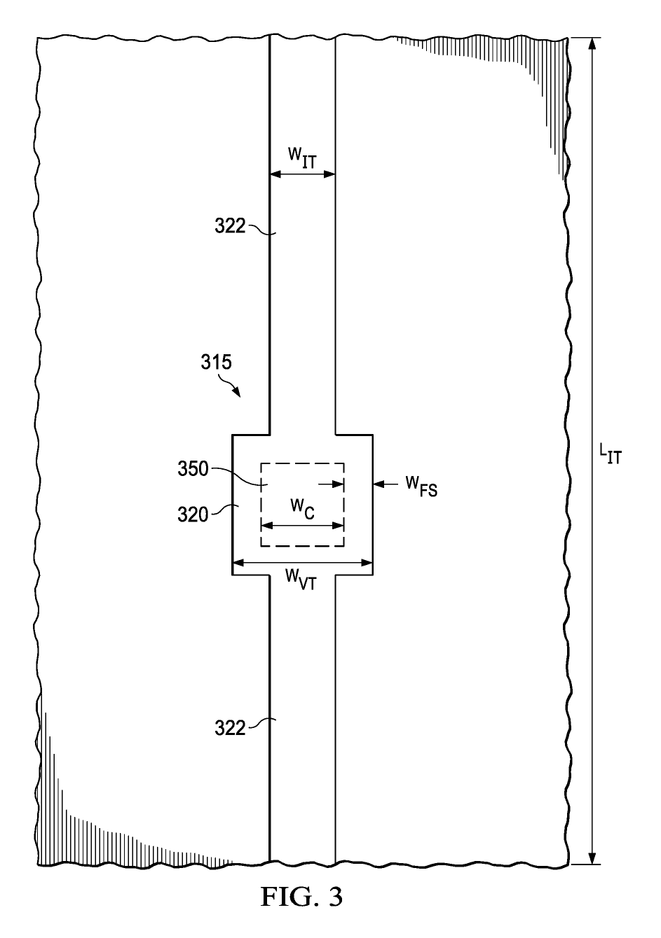

FIG. 3 illustrates a top view of a example trench/opening 315 formed according to the techniques shown in FIGS. 1A-1G discussed above. Elements numbered as 3xx in FIG. 3A may correspond with elements numbered 1xx in FIGS. 1A-1G. The example trench/opening 315 includes an interconnect trench 322 with a wider via trench 320 arranged along the length of the interconnect trench 322. FIG. 3 also shows the location of a via cavity 334 (dashed lines) defined by subsequent deposition of a conformal fill layer in the via trench, e.g., as discussed above. A via opening may be formed by etching through the via cavity 334, such that the via opening dimensions (e.g., the via opening width in both orthogonal directions) are equal or approximately equal (e.g., ±10% or ±15%) to the via cavity dimensions.

FIG. 3 shows example dimensional parameters of the structure, including a length LIT and width W_{IT} of interconnect trench 322, a width W_{VT} of via trench 320, a width W_{FS} of a fill layer sidewall W_{FS}, and a width W_{C} of via cavity 334 formed within via trench 320.

The interconnect trench length LIT is greater than or equal to the via trench width W_{VT}.

As discussed above, the via trench width W_{VT} may be greater than two times the fill layer sidewall width W_{FS}, to define a via trench cavity width W_{C} (which defines the via opening width W_{VO} after etching through the vie trench cavity to form the via opening 350, e.g., as discussed above). Thus, W_{VT}=2*W_{FS}+W_{C}. In addition, as discussed above, the interconnect trench width W_{IT} may be less than or equal to two times the fill layer sidewall width W_{FS}. In other words, W_{IT}≤2*W_{FS}.

FIGS. 4A-4D illustrate example dimensional parameters of metal vias and interconnects formed according to an example embodiment of the invention, as compared with a conventional design.

FIG. 4A is a top view of a pair of metal lines 400A and 400B, each having a via interconnect 402A, 402B and underlying via 404A, 404B arranged along each line, according to an embodiment of the present invention. In contrast, FIG. 4B is a top view of a pair of metal lines 410A and 410B having a via 412A and 412B arranged along each line, according to a conventional design. As shown, the pitch “P” between adjacent lines 400A, 400B may be identical to the pitch provided by the conventional design. Further, the outer edge spacing “O” between adjacent lines 400A, 400B may be identical to the outer edge spacing provided by the conventional design. Still further, the spacing “S” providing isolation between the adjacent lines 400A, 400B may be identical or better than spacing provided by the conventional design.

FIG. 4C is a cross-sectional view of metal lines 400A and 400B, taken through line 4C-4C shown in FIG. 4A, which extends through metal line 400A and through via interconnect 402B and via 404B extending downwardly from via interconnect 402B. FIG. 4D is a cross-sectional view of metal lines 400C and 400C, taken through line 4D-4D shown in FIG. 4B, which extends through metal line 410A and through via metal line 410B underlying via 412B extending downwardly from metal line 410B.

As shown in FIGS. 4A-4D, metal lines 400A and 400B according to the present invention may have a narrower width than the conventional metal lines 410A and 410B. Thus, in some embodiments, as shown in FIG. 4C, metal lines 400A and 400B may be formed with a taller height H_{TI} than that of the conventional metal lines (H_{ref}) to compensate for the narrower width, to thereby provide the same or similar line resistance.

FIGS. 5A-5H are cross-sectional views illustrating another example method for forming conductive vias and interconnects in a semiconductor device using a single mask dual damascene process, according to another example embodiment. The example method of FIGS. 5A-5H may represent an alternative to the example method of FIGS. 1A-1G. The method shown in FIGS. 5A-5H in similar to the method of FIGS. 1A-1G, but using a multi-layered conformal fill layer 530 instead of the single-layer fill layer 130 used in the method of FIGS. 1A-1G. In particular, the example embodiment shown in FIGS. 5A-5H may utilize a multi-layered fill layer 530 consisting of a titanium nitride sublayer and a tungsten sublayer, as discussed below

As shown in FIG. 5A, a semiconductor device structure 500 may include a lower metal 502 (e.g., metal interconnect or device) formed in a substrate or dielectric region 105 below a bottom barrier 504. The lower barrier layer 504 may be of a same material as a later-formed hard mask 550, discussed below. A non-conductive layer 506, e.g., an inter-metal dielectric (IMD) layer, may be formed above the lower barrier layer 502. A hard mask 510 may be arranged or formed above the IMD layer 506. Hard mask 510 may include a number of openings, including a first hard mask opening 512 having a first width for forming a conductive via and a second hard mask opening 514 having a first width smaller than the first width, for forming a conductive interconnect, as discussed below.

An etch may be performed through the first and second hard mask openings 512 and 514 to form a via trench 520 and an interconnect trench 522 in the IMD layer 506. As shown, the via trench 520 may have a width W_{VT}, and interconnect trench 522 may have a width W_{IT} less than the via trench width W_{VT}, wherein widths W_{VT} and W_{IT} are defined by the respective widths of the first and second hard mask openings 512 and 514. As discussed below, via trench width W_{VT} and interconnect trench width W_{IT} may be selected (by selected dimensioning of the hard mask openings 512 and 514) based on a thickness or width of a fill layer subsequently formed over the structure and extending into the via trench 520 and interconnect trench 522. Further, in some embodiments, the via trench width W_{VT} may be approximately the same as, or greater than, the corresponding width of lower metal 504.

Via trench 520 and interconnect trench 522 may thus be formed using only a single hard mask, and thus only a single photolithography process.

As shown in FIG. 5B, a sacrificial conformal fill layer (also referred to as a spacer layer) 530 may be deposited over the hard mask 510 and extending down into via trench 520 and interconnect trench 522. In this example embodiment, sacrificial conformal fill layer 530 may include a thin titanium nitride sublayer 530A deposited first, followed by a thicker tungsten sublayer 530B deposited over the thin nitride sublayer 530A.

As shown in FIG. 5B, the conformal multi-layer fill layer 530 may be formed with a selected thickness that defines vertical sidewall regions 540 within via trench 520 with a selected sidewall width W_{FS}. The width W_{VT} of via trench 520 may be greater than double the fill layer sidewall width W_{FS}, such that a via trench cavity 534 is defined between opposing sidewall regions 540 of fill layer 530. In contrast, the width W_{IT} of interconnect trench 522 may be less than or equal to double the fill layer width in the via trench, W_{FS}, such that the full width W_{IT} of interconnect trench 522 is filled with the multi-layered fill layer, as shown.

As shown in FIG. 5C, a wet or dry chemical etch may be performed to remove a thickness of tungsten layer 530B, and extend partially into the TiN layer 530A. The etch may remove the tungsten layer 530B except for a portion remaining in the interconnect trench 522. After the etch, at least a partial thickness of titanium nitride sublayer 530A may remain over hard mask 510 and extending into via trench 520 and interconnect trench 522, and a partial height of the tungsten layer 530B may remain in the interconnect trench 522.

As shown in FIG. 5D, a further etch may be performed to remove portions of the TiN layer 530A over hard mask 510 and at the bottom of via trench 520. In some embodiments, the etch may be controlled to leave portions of TiN layer 530A on the sidewalls of via trench 520, to protect the via trench 520 during a subsequent via etch.

As shown in FIG. 5E, a further etch may be performed through the via trench 520 to define a via opening 550 extending from the bottom of the via trench 520 and having a via opening width W_{VO}. The etch may be selective to hard mask 510, TiN layer 530A, and/or the remaining portion of tungsten layer 530B within interconnect trench 522, thus etching only through the IMD layer 506 at the exposed region between the fill layer sidewall regions 530A within via trench 520. For example, the etch may be an anisotropic fluorine etch.

Thus, via opening 550 may be self-aligned by via trench 520 (and further by the fill layer sidewall regions, if still existing after the etch shown at FIG. 5D). The etch may stop on the lower barrier layer (e.g., hard mask material) 502 to expose an upper surface 552 of lower barrier layer 502.

As shown in FIG. 5F, all remaining tungsten 530A may be removed.

As shown in FIG. 5G, a barrier etch may be performed through the region of the lower barrier layer 502 exposed through via opening 550 (i.e., at exposed surface 552) and stopping at or below a top surface of the underlying lower metal region 504, to thereby extend the via opening 550 downwardly into contact with the lower metal region 504. The etch may also remove hard mask 510, or hard mask 510 may be removed in a separate step. In some embodiments, the fill layer sidewall regions 530A within via trench 520 and the fill layer 530A within interconnect trench 522 may protect the IMD, e.g., a low-k dielectric, during the etch process, such that no ash is required.

In some embodiments, the tungsten removal shown in FIG. 5F may be achieve by the etch shown at FIG. 5G, such that the two steps may be performed by a single etch.

As shown in FIG. 5G, a metallization and chemical-mechanical planarization (CMP) may be performed to (a) fill via opening 550 to form a conductive via 570 in contact with lower metal contact 504 and having a via width W_{V}, (b) fill via trench 520 to form a conductive via interconnect 574 overlying and in contact with via 570, and (c) fill interconnect trench 522 to form a conductive trench interconnect 580 having a width W_{TI}. Any suitable metal or other electrically conductive material may be used for the metallization, e.g., copper, tungsten, etc.

FIG. 6 illustrates an example metal-oxide-metal (MOM) capacitor 600 formed according to one embodiment of the invention. MOM capacitor 600 may include an array of trench-style capacitor structures 680 formed according to techniques disclosed herein. For example, each conductive capacitor structure 680 may be formed in the manner of a trench interconnect 180 or 580 as discussed above, and thus may be formed with a narrower width W and with tighter spacing (e.g., reduced pitch P) as compared with conventional techniques. The reduced pitch may provide improved or maximum capacitance.

1. A method of forming conductive structures in a semiconductor device, the method comprising:
forming a mask over a non-conductive structure, the mask including a first mask opening and a second mask opening, the first mask opening having a greater width than the second mask opening;
etching through the first and second mask openings into the non-conductive structure to define:
a via trench having a via trench opening width defined by the first mask opening; and
an interconnect trench having an interconnect trench width defined by the second mask opening and smaller than the via trench width;
depositing a fill layer extending into both the via trench and the interconnect trench such that:
the fill layer extending into the via trench fills only a portion of the via trench width to thereby define an open via trench cavity; and
the fill layer extending into the interconnect trench fills the full interconnect trench width;
etching through the via trench cavity to form a via opening extending downwardly from the via trench;
removing the fill layer from the via trench and the interconnect trench;
filling the interconnect trench, the via trench, and the via opening with a conductive material to form (a) a trench interconnect in the interconnect trench, (b) a via interconnect in the via trench, and (c) a via in the via opening, wherein the via extends downwardly from the via interconnect.

2. The method of claim 1, wherein the method includes only a single mask.

3. The method of claim 1, wherein the conductive via comprises a metal dual damascene via.

4. The method of claim 1, wherein the first and second mask openings form a contiguous opening, such that the via trench and interconnect trench are contiguous, and such that the resulting via interconnect and trench interconnect are likewise contiguous.

5. The method of claim 1, wherein the first and second mask openings comprise discrete, spaced-apart openings, such that the resulting via interconnect and interconnect trench are discrete, spaced-apart structures.

6. The method of claim 1, wherein;
the fill layer has a fill layer width;
the via trench width is more than double the fill layer width; and
the interconnect trench width is less than or equal to double the fill layer width.

7. The method of claim 1, wherein the via opening has a via opening width that is less than the via trench width.

8. The method of claim 1, wherein the via opening is self-aligned by the fill layer extending in the via trench.

9. The method of claim 1, wherein:
the via trench and the interconnect trench extend down to a common depth; and
the via opening extends below the via trench.

10. The method of claim 1, wherein the fill layer comprises silicon nitride or silicon carbide.

11. The method of claim 1, wherein the fill layer includes multiple sublayers.

12. The method of claim 9, wherein the fill layer comprises a TiN sublayer and a tungsten sublayer.

13. The method of claim 1, wherein etching through the via trench cavity to form the via opening comprises etching through a barrier or hard mask layer to expose a top surface of a conductive contact.

14. A method of forming conductive structures in a semiconductor device, the method comprising:
etching a semiconductor device structure to form:
a via trench having a lateral via trench opening width in a first lateral direction; and
an interconnect trench having a lateral interconnect trench width in the first lateral direction, the lateral interconnect trench width being smaller than the lateral via trench width;
performing a fill process to:
fill the via trench fills across only a portion of the lateral via trench width to thereby define a via trench cavity in the unfilled portion of the via trench; and
fill interconnect trench across the full interconnect trench width;
etching through the via trench cavity to form a via opening extending downwardly from the via trench; and
filling the interconnect trench, the via trench, and the via opening with a conductive material to form (a) a trench interconnect in the interconnect trench, (b) a via interconnect in the via trench, and (c) a via in the via opening, wherein the via extends downwardly from the via interconnect.

15. The method of claim 14, comprising removing fill material deposited during the fill process prior to filling the interconnect trench, the via trench, and the via opening with the conductive material.

16. The method of claim 14, wherein the via trench is contiguous with the interconnect trench are contiguous, such that the resulting via interconnect is contiguous with the trench interconnect.

17. The method of claim 14, wherein the via trench and interconnect trench are discrete, non-contiguous trenches, such that the resulting via interconnect trench interconnect are discrete, non-contiguous structures.

18. The method of claim 14, wherein the via opening has a lateral via opening width in the first direction that is less than the lateral via trench width.

19. The method of claim 14, wherein the via opening is self-aligned by fill material sidewalls formed in the via trench during the fill process.

20. The method of claim 14, wherein:
the via trench and the interconnect trench extend down to a common depth; and
the via opening extends below the via trench.
